(19) United States
(12) Patent Application Publication
(10) Pub. No.: US 2009/0254797 A1
(43) Pub. Date: Oct. 8, 2009

(54) Iterative Signal Receiving Method and Related Iterative Receiver

(76) Inventors: Cheng-Hsuan Wu, Taipei City (TW); Yao-Nan Lee, Kaohsiung City (TW); Jiunn-Tsair Chen, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/368,297

(22) Filed: Feb. 9, 2009

(30) Foreign Application Priority Data
Apr. 8, 2008 (TW) 097112637

(51) Int. Cl. H03M 13/37; H04L 27/06

(52) U.S. Cl. 714/794; 375/341; 714/E11.001

(57) ABSTRACT

Considering both performance and cost of an iterative receiver, the present invention provides an iterative signal receiving method for a wireless communications system. The iterative signal receiving method includes utilizing a channel estimating (CE) process to perform channel estimation for a received signal according to first log-likelihood ratio (LLR) data to generate second LLR data, and then generating the first LLR data according to an error correction code (ECC) decoding process and the second LLR data. When the ECC decoding process is a convolutional decoding process, the CE process is a zero-forcing process, a minimum mean square error (MMSE) process or an interpolation-based process. When the ECC decoding process is a low density parity check code (LDPC) decoding process, the CE process is a maximum likelihood (ML) process or a maximum a posteriori (MAP) process.

### BACKGROUND OF THE INVENTION

1. Field of the Invention

The present invention relates to a signal receiving method and related device for a wireless communication system, and more particularly, to an iterative signal receiving method and related device for use in a wireless communication system.

2. Description of the Prior Art

In wireless communication system, a transmitter can process transmission data with encoding, modulating, interleaving processes, and other signal processes in advance and then transforms the processed transmission data into wireless signals. When traveling through a wireless channel, the wireless signals usually suffer frequency or time selective fading, and thereby cause signal distortion. As a result, a receiver needs channel estimation, demodulating, error correction code decoding (ECC decoding) and other receiving processes for recovery of the distorted received wireless signals.

A typical receiver includes a channel estimator and an ECC decoder. The channel estimator estimates channel responses to recover received signals from phase and amplitude distortion, where the ECC decoder corrects decision error bits of the received signals according to an error correction code (ECC). In recent years, the receiver gradually evolves to an iterative receiver due to adoption of a Turbo Code. In the iterative receiver, the channel estimator and the ECC decoder iteratively exchanges soft information with each other to lower a bit error rate (BER).

Commonly used ECCs include a convolutional code, a low density parity check code (LDPC) and the turbo code. As being well known in the art, the convolutional code is classified as an ECC with a weaker error correction capability and lower computational complexity, whereas the LDPC and the turbo code are classified as ECCs with a stronger error correction capability and higher computational complexity

Commonly used channel estimation techniques are zero-forcing (ZF), minimum mean square error (MMSE), interpolation-based estimation, maximum likelihood (ML), and maximum a posteriori (MAP) processes. As being well known in the art, the ZF, MMSE, and linear or one-dimensional interpolation-based processes are classified as channel estimation techniques with lower computational complexity and poorer channel estimation quality, whereas the ML and MAP processes are classified as channel estimation techniques with higher computational complexity and better channel estimation quality.

However, the prior art does not specify any standard approaches or criteria about compatibility of the channel estimation techniques and the ECC decoders for effective utilization of the soft information. As a result, if the iterative receiver randomly selects a channel estimation technique to work with a certain ECC decoder, the soft information utilized for purifying the channel estimates can ruin the channel estimation, thereby degrading performance of the iterative receiver. For example, when the iterative receiver selects the ML to work with the convolutional code decoder, the BER cannot effectively be reduced although the complexity and cost become higher due to adoption of ML. Thus, it is an important subject to select a compatible combination of the channel estimation technique and the ECC decoder in consideration of system performance, complexity, and cost.

### SUMMARY OF THE INVENTION

It is therefore an objective of the present invention to provide an iterative signal receiving method of a wireless communication system and related iterative receiver adopting a compatibility criterion for the convolutional code and the LDPC to benefit the BER performance with effective cost.

According to the present invention, an iterative signal receiving method for a wireless communication system is disclosed and includes, according to first log-likelihood ratio data, utilizing a channel estimation process to perform channel estimation for a received signal to generate second log-likelihood ratio data, and then, according to an error correction code decoding algorithm and the second log-likelihood ratio data, generating the first log-likelihood ratio data.

According to the present invention, an iterative receiver of a wireless communication system is further disclosed and includes a soft channel estimator and an ECC decoder. The soft channel estimator includes a first input terminal for receiving a received signal, a second input terminal for receiving first log-likelihood ratio data, and an output terminal for outputting second log-likelihood ratio data. The soft channel estimator is used for utilizing a channel estimation process to perform channel estimation for a received signal according to the first log-likelihood ratio data to generate the second log-likelihood ratio data. The ECC decoder includes an input terminal for receiving the second log-likelihood ratio data and an output terminal for outputting the first log-likelihood ratio data. The ECC decoder is used for generating the first log-likelihood ratio data according to an error correction code decoding algorithm and the second log-likelihood ratio data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an iterative signal receiving process according to an embodiment of the present invention.

FIG. 2 is a schematic diagram of an iterative receiver according to an embodiment of the present invention.

FIG. 3 is a schematic diagram of an iterative receiver for a multi-carrier wireless communication system according to an embodiment of the present invention.

FIG. 4 is a schematic diagram of the received signal of the iterative receiver according to FIG. 3.

### DETAILED DESCRIPTION

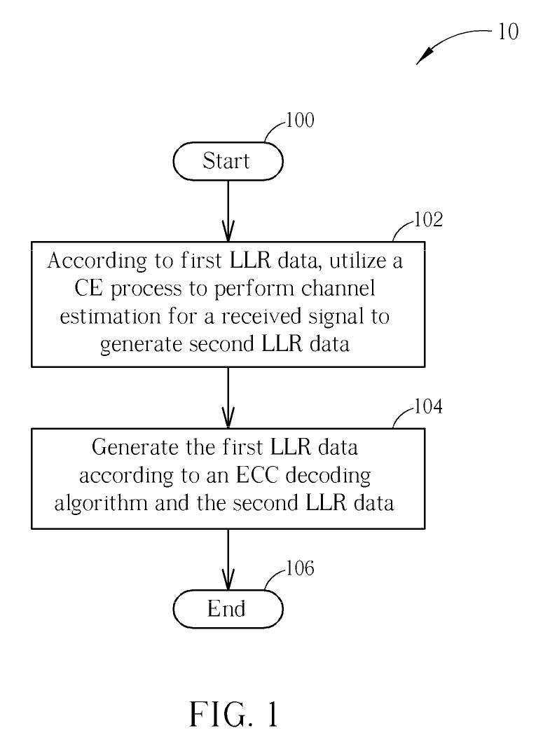

Please refer to FIG. 1, which is a schematic diagram of an iterative signal receiving process 10 according to an embodiment of the present invention. The iterative signal receiving process 10 is utilized in a receiver of a wireless communication system and includes the following steps:

Step 100: Start.

Step 102: According to first log-likelihood ratio (LLR) data, utilize a channel estimation (CE) process to perform channel estimation for a received signal to generate second LLR data.

Step 104: Generate the first LLR data according to an ECC decoding algorithm and the second LLR data.

Step 106: End.

In the iterative signal receiving process 10, Step 102 is utilized for realizing channel estimation, and the ECC decoding algorithm in Step 104 is a soft input soft output (SISO) algorithm. Both of the first and second LLR data is soft information. According to the iterative signal receiving process 10, the first LLR data is used as “a priori” information corresponding to the received signal. The CE process is utilized to perform channel estimation for the received signal according to the first LLR data and thereby an initial channel response is obtained to generate the second LLR data, which is used as “a posteriori” information as well as “a priori” information for the received signal. The first LLR data is generated according to the ECC decoding algorithm and the second LLR data. For interactive operation, the newly generated first LLR data is provided as “a priori” information again for channel estimation. Thus, an iterative loop for exchanging soft information is formed between the channel estimation and ECC decoding

In the iterative signal receiving process 10, the CE process, for example, can be a zero-forcing (ZF) process, a minimum mean square error (MMSE) process, or an interpolation-based process when the ECC decoding algorithm is a convolutional decoding algorithm. When the ECC decoding algorithm is a low density parity check code (LDPC) decoding algorithm, the CE process, for example, can be a maximum likelihood (ML) process or a maximum a posteriori (MAP) process. As can be seen from the above, the convolutional decoding algorithm is compatible with the CE processes with lower computational complexity and poorer channel estimation quality, whereas the LDPC decoding algorithm is compatible with the CE processes with higher computational complexity and better channel estimation quality. With the abovementioned arrangements for the CE processes and the ECC decoding algorithms, the iterative signal receiving process 10 can purify channel estimates corresponding to the channel response through iteratively-generated first and second LLR data to have the estimated channel response more closing to the real channel response, thereby benefiting bit error rate (BER) performance of the receiver.

The convolutional code dominates the receiving performance (i.e. BER performance) of the iterative signal receiving process 10 due to the weaker error correction capability. As a result, the receiving performance cannot be effectively improved when the CE processes with better channel estimation quality works with the convolutional code. On the other hand, the LDPC needs to work with the CE processes with better channel estimation quality due to the stronger error correction capability to enhance reliability of generated soft information.

Preferably, the iterative signal receiving process 10 is utilized in a multi-carrier wireless communication system where the received signal includes a plurality of pilot and data symbols corresponding to different subcarriers. Since ideal values of the pilot symbols, as well known in the art, are symbols jointly known by the receiver and related transmitter, the receiver can utilize the received pilot symbols and the ideal pilot symbols to generate initial values of the first and second LLR data. The pilot and data symbols are used for continuously purifying the channel estimates.

According to the system requirement, the ordinary skill in the art can additionally introduce signal processes of interleaving, de-interleaving, and bit demapping into the iterative signal receiving process 10. For example, the second LLR data undergoes the de-interleaving process before being inputted for ECC decoding, and accordingly the first LLR data undergoes the interleaving process before being inputted for the CE process.

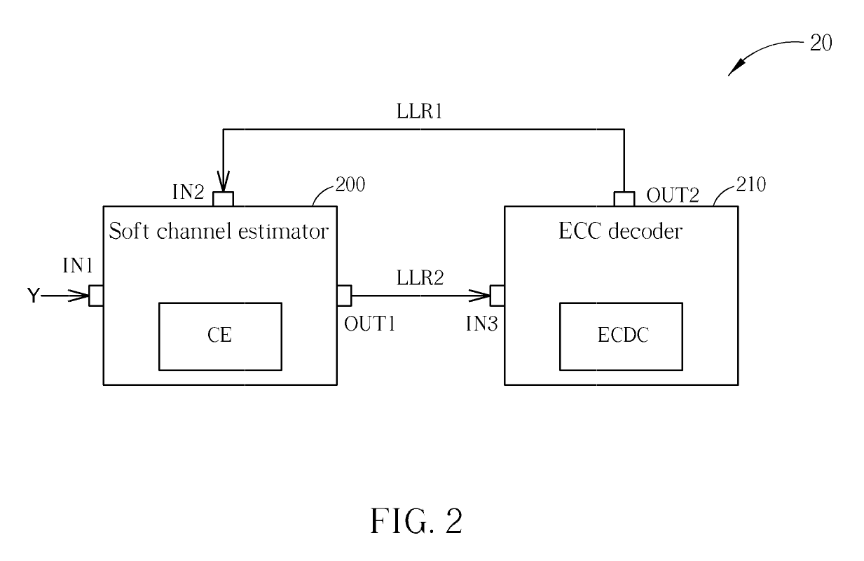

Please refer to FIG. 2, which is a schematic diagram of an iterative receiver 20 according to an embodiment of the present invention. The iterative receiver 20 is preferably used in a multi-carrier wireless communication system and includes a soft channel estimator 200 and an ECC decoder 210. The soft channel estimator 200 is a channel estimator operating with soft information and includes input terminals IN1 and IN2, and an output terminal OUT1. The input terminal IN1 is utilized for receiving a received signal Y passing through a wireless channel, whereas the input terminal IN2 is utilized for receiving first log-likelihood ratio data LLR1 outputted by the ECC decoder 210. The soft channel estimator 200 is used for utilizing a channel estimation process CE to perform channel estimation for the received signal Y according to the first log-likelihood ratio data LLR1. With the soft channel estimator 200, a rough, initial channel response H is obtained for generation of second log-likelihood ratio data LLR2 to generate the second log-likelihood ratio data.

The output terminal OUT1 is utilized for outputting the second log-likelihood ratio data LLR2 to the ECC decoder 210. The ECC decoder 210 is a soft-input, soft-output decoder and includes an input terminal IN3 for receiving the second log-likelihood ratio data LLR2 and an output terminal OUT2 for outputting the first log-likelihood ratio data LLR1. The ECC decoder 210 is used for generating the first log-likelihood ratio data LLR1 according to an error correction code decoding algorithm ECDC and the second log-likelihood ratio data LLR2.

In the iterative receiver 20, the channel estimation process CE of the soft channel estimator 200, for example, can be a ZF process, a MMSE process, or an interpolation-based process when the ECC decoding algorithm ECDC is a convolutional decoding algorithm. When the ECC decoding algorithm EDEC is a LDPC decoding algorithm, the soft channel estimator 200 can select a ML or MAP process as the channel estimation process CE. With the abovementioned arrangement, the iterative receiver 20 can continuously purify the channel response H through the first log-likelihood ratio data LLR1 and the second log-likelihood ratio data LLR2 such that the channel response H becomes more and more close to the real channel response.

The convolutional code dominates the receiving performance of the iterative receiver 20 due to the weaker error correction capability. Thus, if the iterative receiver 20 adopts a strong channel estimation process CE for the soft channel estimator 200 when the convolutional code decoding algorithm is used, the receiving performance of the iterative receiver 20 cannot gain improvement even though the system complexity and cost have increased. On the other hand, due to the strong error correction capability, the ECC decoder 210 using the LDPC shall cooperate with the soft channel estimator 200 using a strong channel estimation process CE to enhance reliability of the exchanged soft information.

In the multi-carrier wireless communication system, the received signal Y tends to include a plurality of pilot and data symbols. The ideal symbol of the pilot symbols are known by the iterative receiver 20 so that the initial values of the first log-likelihood ratio data LLR1 and the second log-likelihood ratio data LLR2 can be derived from the ideal and received pilot symbols.

Preferably, a deinterleaver is installed between the output terminal OUT1 of the soft channel estimator 200 and the input terminal IN3 of the ECC decoder 210 and used for de-interleaving the second log-likelihood ratio data LLR2. In addition, an interleaver is installed between the input terminal IN2 of the soft channel estimator 200 and the output terminal OUT2 of the ECC decoder 210 and used for interleaving the first log-likelihood ratio data LLR1. The iterative receiver 20 preferably supports different signal modulations, such as Quadrature Phase Shift Keying (QPSK) and 16-level Quadrature Amplitude Modulation (16-QAM). In this situation, the soft channel estimator 200 employs a soft bit demapper for demapping the received signal Y according to an in-use signal modulation.

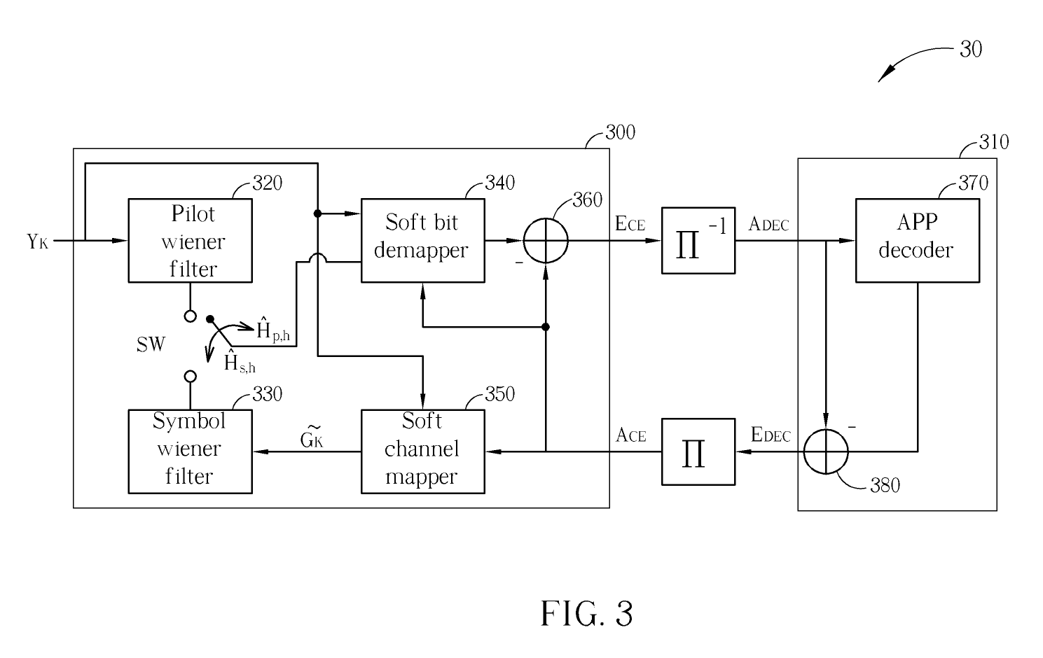

Please refer to FIG. 3, which is a schematic diagram of an iterative receiver 30 for a multi-carrier wireless communication system according to an embodiment of the present invention. A transmitter corresponding to the iterative receiver 30 generates data symbols based on QPSK modulation and a Gray code, and inserts a pilot symbol every (L-1) data symbols to form a frequency domain symbol Xₖ, where QPSK signals are represented by alphabets {s₀₀,s₀₁,s₁₀,s₁₁,}={+1,+j,−,−j}. The frequency domain symbol Xₖ is then modulated into orthogonal subcarrier signals numbered from 0 to (K−1), and next padded with cyclic prefix to generate time-domain signals before going through a wireless channel.

The iterative receiver 30 received a received signal Y having K symbols from the wireless channel, and utilizes an observation window ψₕ to obtain part of symbols in the received signal Y to estimate a channel response of the hₜₕ subcarrier, where 0≦h≦K−1. Please note that ψₕ is also utilized to represent all the subcarrier indices within the observation window of the hₜₕ subcarrier.

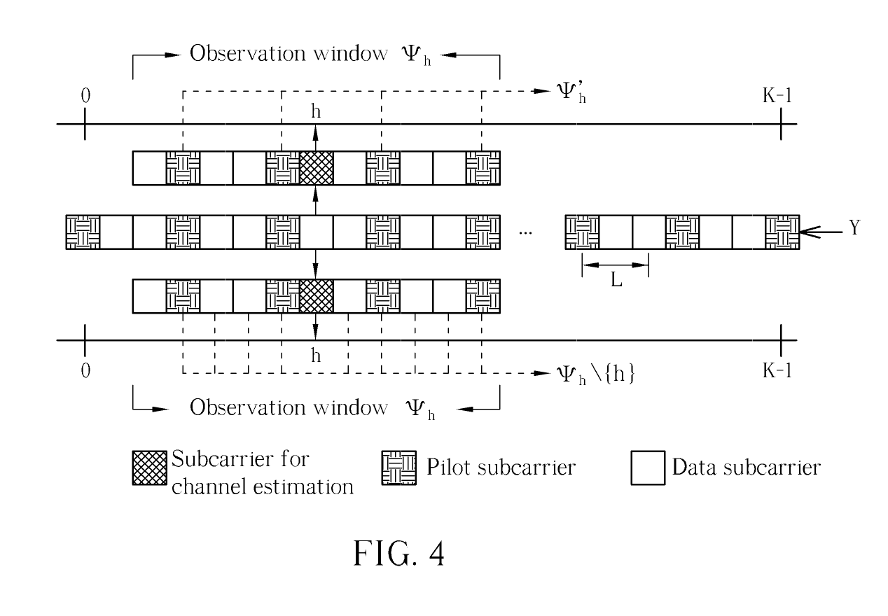

Please refer to FIG. 4, which is a schematic diagram of the received signal Y of the iterative receiver 30 according to an embodiment of the present invention. As can be seen from FIG. 4, two consecutive subcarriers carrying data symbols are inserted between every two subcarriers carrying pilot symbols. The observation window ψₕ captures data of eleven subcarriers each time, where the central subcarrier of the eleven subcarriers is defined as the hₜₕ subcarrier. In addition, ψ′ₕ and ψ\{h} are both subsets of ψₕ, and usage thereof are described below.

The iterative receiver 30 includes a soft channel estimator 300, an ECC decoder 310, an interleaver Π and a deinterleaver Π⁻¹. The soft channel estimator 300 includes a pilot wiener filter 320, a symbol wiener filter 330, a soft bit demapper 340, a soft channel mapper 350, a switch SW and an adder 360. The ECC decoder 310 includes an APP (A Posteriori probability) decoder 370 and an adder 380. The APP decoder 370 is a soft-input soft-output decoder based on the convolutional code for correcting errors for the input data according to soft information outputted by the soft channel estimator 300.

For each observation window ψₕ, the iterative receiver 30 utilizes two rounds of channel estimation. The first round is pilot-aided. The second round simultaneously makes use of pilot and data symbols as ψₕ\{h} shown in FIG. 4 and purifies channel estimates via the soft information exchanged between the soft channel estimator 300 and the ECC decoder 310 to reduce the BER.

When the iterative receiver 30 begins to receive the received signal Y, the switch SW is predetermined to couple to the pilot wiener filter 320 that is used for performing the first round pilot-aided channel estimation with the received signal Y and the ideal pilot symbols. The channel estimates Ĥ_{P,h} are derived from the followings:

$${\hat{H}}_{P , h} = \{ \begin{matrix}{\tilde{H}}_{h} = {Y}_{h} / {X}_{h} , & h ∈ {Ψ}^{′} \\ {( {\underline{ω}}_{P , h} )}^{T} \cdot {\underline{\tilde{H}}}_{P , h} = {\sum }_{k ∈ {Ψ}_{h}^{′}} {ω}_{P , h , k} \cdot \tilde{H} , & 0 \leq h \leq K - 1 \& h ∉ {Ψ}^{′}\end{matrix} \qquad ( 1 )$$

where ψ′ denotes the set of subcarrier indices of all the pilot symbols in the received signal Y, and Ĥₕ, Yₕ and Xₕ are the channel estimate, the received signal and the ideal pilot symbol of the hₜₕ subcarrier respectively. ω_{P,h}=[{ω_{P,h,k}|k∈ψ′ₕ}]^{T} is the coefficient column vector of the pilot wiener filter 320, and \tilde{H}_{P,h}=[{\tilde{H}ₖ|k∈ψ′ₕ}]^{T}, where ψ′ₕ contains the subcarrier indices of the pilot symbols within the observation window ψₕ, and is depicted in FIG. 4.

Furthermore, the filter coefficients ω_{P,h} of the pilot wiener filter 320 are obtained by solving the well-known Wiener-Hopf equation, which is expressed as

(ω_{P,h})^{T}=r_{H\tilde{H},h}^{T}·R_{\tilde{H}\tilde{H},h}⁻¹ (2)

with

r_{HH,h}^{T}=[{Rₕ₋ₖ|k∈ψ′ₕ}]^{T} (3)

and

$${R}_{\tilde{H} \tilde{H} , h} = [ \begin{matrix}{R}_{0} + {N}_{0} & {R}_{L}^{*} & … & {R}_{( {n}_{h} - 1 ) L}^{*} \\ {R}_{L} & {R}_{0} + {N}_{0} & … & {R}_{( {n}_{h} - 2 ) L}^{*} \\ ⋮ & ⋮ & ⋱ & ⋮ \\ {R}_{( {n}_{h} - 1 ) L} & {R}_{( {n}_{h} - 2 ) L} & … & {R}_{0} + {N}_{0}\end{matrix} ] \qquad ( 4 )$$

where {Rₖ} are complex autocorrelation functions of a wideband channel response, nₕ is the number of pilot symbols within the observation window ψₕ, and N₀/2 is power spectral density of additive white Gaussian noise (AWGN).

As can be seen from the above, the pilot wiener filter 320 directly divides the received signal Y by the corresponding ideal pilot symbols when the hₜₕ subcarrier of the observation window ψₕ is a pilot symbol, so as to obtain the channel estimates of the pilot subcarrier. When the hₜₕ subcarrier is a data symbol, the pilot wiener filter 320 utilizes the obtained channel estimates to calculate the channel estimates of the data subcarrier through a one-dimensional interpolation process.

After the first round pilot-aided channel estimation is performed, the soft channel mapper 350 with assistance of the adder 360, generates log-likelihood ratio (LLR) data A_{CE} and E_{CE} according to the received signal Y and the channel estimates Ĥ_{P,h}, where the LLR data A_{CE} and E_{CE} are intrinsic and extrinsic a posteriori log-likelihood data respectively. The deinterleaver Π⁻¹ generates LLR data A_{DCE} after deinterleaving the LLR data E_{CE}. The ECC decoder 310 and the adder 380 co-work to generate LLR data E_{DCE} after error correction is performed. The interleaver Π generates the LLR data A_{CE} after interleaving the LLR data E_{DCE}. Each time a data process of the deinterleaver Π⁻¹, the ECC decoder 310, and the interleaver Π is performed, the LLR data A_{CE} is renewed and then applied to the soft channel mapper 350 and the symbol wiener filter 330 to trigger the second round channel estimation. After the first round pilot-aided channel estimation is finished, the switch SW is switched to couple with the symbol wiener filter 330, and the channel estimates \tilde{H}ₕ obtained in the first round pilot-aided channel estimation are reused in the second round.

In the second round, the pilot information and the soft information (i.e. the LLR data A_{CE}) is used for further purifying the channel estimates. According to the received signal Y and the LLR data A_{CE}, the soft channel mapper 350 first constructs temporary soft channel estimates for all the subcarriers as follows:

$${\tilde{G}}_{k} = \{ \begin{matrix}{\tilde{H}}_{k} = {Y}_{k} / {X}_{k} , & k ∈ {Ψ}^{′} \\ f ( {Y}_{k} , {A}_{CE} ( {c}_{k , 1} , {c}_{k , 2} ) ) , & 0 \leq k \leq K - 1 and h ∉ {Ψ}^{′}\end{matrix} \qquad ( 5 )$$

where c_{k,i} denotes the ith binary bit of the kth data symbol, and i is 1 or 2 since the received signal Y is generated based on the QPSK modulation. f(Yₖ,A_{CE}(c_{k,1},c_{k,2})) is a channel mapping function, which is preferably expressed as

$$f ( {Y}_{k} , {A}_{CE} ( {c}_{k , 1} , {c}_{k , 2} ) ) = {max}_{p ( {s}_{ij} )} [ p ( {s}_{ij} ) \cdot \frac{{Y}_{k}}{{s}_{ij}} ] + [ 1 - p ( {s}_{ij} ) ] \cdot {\hat{H}}_{P , k} \qquad ( 6 )$$

where sᵢⱼ is the OPSK signal whose signal constellation is {s₀₀,s₀₁,s₁₀,s₁₁,}={+1,+j,−1,−j}, and p(sᵢⱼ) is occurrence probability of the OPSK signal sᵢⱼ.

Through the equations (5) and (6), the soft channel mapper 350 outputs the temporary soft channel estimates \tilde{G}ₖ to the symbol wiener filter 330 for purifying the channel estimates. With the symbol wiener filter 330, estimates Ĥ_{s,h} of the channel response at the hₜₕ subcarrier can be further purified as follows:

$${\hat{H}}_{S , h} = \{ \begin{matrix}{\tilde{H}}_{h} = {Y}_{h} / {X}_{h} , & h ∈ {Ψ}^{′} \\ {( {\underline{ω}}_{S , h} )}^{T} \cdot {\underline{\tilde{H}}}_{S , h} = {\sum }_{k ∈ {Ψ}_{h}^{′} ∖ \{ h \}} {ω}_{S , h , k} \cdot {\tilde{G}}_{k} , & 0 \leq h \leq K - 1 and h ∉ {Ψ}^{′}\end{matrix} \qquad ( 7 )$$

where ω_{s,h}=[{ω_{S,h,k}|k∈ψₕ\{h}}]^{T} is a coefficient column vector of the symbol wiener filter 330, and \tilde{H}_{S,h}=[{\tilde{G}ₖ|k∈ψₕ\{h}}]^{T}. Subcarrier distribution of the subset ψₕ\{h} is shown in FIG. 4. Similarly, the filter coefficients ψ_{S,h} are derived from the equations (2), (3) and (4).

In the second round channel estimation, the soft channel mapper 350 renews the LLR data ECE according to the received signal Y_{K} and the channel estimates Ĥ_{S,h} after the symbol wiener filter 330 generates the channel estimates Ĥ_{S,h}. After the LLR data E_{CE} undergoes deinterleaving, error correction, and interleaving, the LLR data A_{CE} is renewed and applied to the soft channel mapper 350 for the channel estimate purification. As can seen from the above, the soft channel estimator 300 and the ECC decoder 310 form a loop iteratively exchanging soft information.

Please note that, instead of a convolutional code decoder, the abovementioned ECC decoder 310 can also be a LDPC decoder. In this situation, those skills in the art can modify the channel mapping function f(Yₖ,A_{CE}(c_{k,1},c_{k,2})) for production of useful soft information.

In conclusion, the embodiment of the present invention provides a criterion that the convolutional code is suitable for a channel estimation process with lower computational complexity and poorer channel estimation quality, whereas the LDPC code is suitable for a channel estimation process with higher computational complexity and better channel estimation quality. Thus, the iterative receiver of the embodiment of the present invention using the criterion can benefit BER performance with cost-effective architecture.

Those skilled in the art will readily observe that numerous modifications and alterations of the device and method may be made while retaining the teachings of the invention.

What is claimed is:

1. An iterative signal receiving method for a wireless communication system, the iterative signal receiving method comprising:
performing a channel estimation for a received signal to generate a second log-likelihood ratio data according to a first log-likelihood ratio data; and
generating the first log-likelihood ratio data according to an error correction code decoding algorithm and the second log-likelihood ratio data.

2. The iterative signal receiving method of claim 1, wherein the step of performing the channel estimation is a zero-forcing (ZF) process, a minimum mean square error (MMSE) process, or an interpolation-based process when the error correction code decoding algorithm is a convolutional decoding algorithm.

3. The iterative signal receiving method of claim 2 further comprising:
de-interleaving the second log-likelihood ratio data; and
interleaving the first log-likelihood ratio data.

4. The iterative signal receiving method of claim 1, wherein the step of performing the channel estimation is a maximum likelihood (ML) process or a maximum a posteriori (MAP) process when the error correction code decoding algorithm is a low density parity check code (LDPC) decoding algorithm.

5. The iterative signal receiving method of claim 1, wherein the received signal comprises a plurality of pilot symbols and a plurality of data symbols.

6. An iterative receiver of a wireless communication system comprising:
a soft channel estimator comprising a first input terminal for receiving a received signal, a second input terminal for receiving a first log-likelihood ratio data, and an output terminal for outputting a second log-likelihood ratio data, the soft channel estimator used for performing a channel estimation for a received signal according to the first log-likelihood ratio data to generate the second log-likelihood ratio data; and
an error correction code (ECC) decoder comprising an input terminal for receiving the second log-likelihood ratio data and an output terminal for outputting the first log-likelihood ratio data, the ECC decoder used for generating the first log-likelihood ratio data according to an error correction code decoding algorithm and the second log-likelihood ratio data.

7. The iterative receiver of claim 6, wherein the soft channel estimator performs a zero-forcing (ZF) process, a minimum mean square error (MMSE) process, or an interpolation-based process when the error correction code decoding algorithm is a convolutional decoding algorithm.

8. The iterative receiver of claim 7 further comprising:
a de-interleaver coupled between the output terminal of the soft channel estimator and the input terminal of the ECC decoder, for de-interleaving the second log-likelihood ratio data; and
an interleaver coupled between the second input terminal of the soft channel estimator and the output terminal of the ECC decoder, for interleaving the first log-likelihood ratio data.

9. The iterative receiver of claim 6, wherein the soft channel estimator performs a maximum likelihood (ML) process or a maximum a posteriori (MAP) process when the error correction code decoding algorithm is a low density parity check code (LDPC) decoding algorithm.

10. The iterative receiver of claim 6, wherein the received signal comprises a plurality of pilot symbols and a plurality of data symbols.
